(19) United States
(12) Patent Application Publication
(10) Pub. No.: US 2026/0113052 A1
(43) Pub. Date: Apr. 23, 2026

(54) ANALOG-TO-DIGITAL CONVERSION

(71) Applicant: Google LLC, Mountain View, CA (US)

(72) Inventors: Kannan Aryaperumal Sankaragomathi, Waterloo (CA); Xichen Li, Seattle, WA (US)

(21) Appl. No.: 19/111,502

(22) PCT Filed: Sep. 16, 2022
(86) PCT No.: PCT/US2022/043826

§ 371 Date: Mar. 13, 2025

(51) Int. Cl. H03M 1/46

(52) U.S. Cl. CPC H03M 1/462; H03M 1/466

(57) ABSTRACT

Methods, systems, and apparatus, for an analog-to-digital converter. One system includes an MSB DAC array configured to generate respective sample values for one or more most-significant bits of an output ADC value, a first LSB DAC array configured to generate respective sample values for one or more least-significant bits of the output ADC value, a second LSB DAC array configured to generate respective sample values for the one or more least-significant bits of the output ADC value, wherein each DAC array in the first LSB DAC array and the second LSB DAC array is configured to alternate between generating an output ADC bit value and a mismatch error value for the output ADC bit value.

### CROSS-REFERENCE TO RELATED APPLICATION

### BACKGROUND

A successive-approximation (SAR) analog-to-digital converter (ADC) converts a continuous analog waveform into a discrete digital representation using a binary search. The most significant bit (MSB) in the ADC is used as an approximate value that is compared to the sample value. In a binary search, the MSB is half of the largest value that can be provided by the ADC. If the sample value is greater than the MSB, then the MSB is retained and the next successive bit is added to the approximate value. In a binary search, the next successive bit is half of the MSB. This process continues until the approximated value of the retained bits is greater than the sample value. If the approximated value is greater than the sample value, then the most recently added bit is not retained to the approximate value. As each individual bit is retained or left out from the approximate value, the approximate value approaches the sample value.

Linearity, e.g., in signal-to-noise-and-distortion-ratios (SNDR), is an important metric that represents or can be used to determine the accuracy of analog-to-digital conversions. One method of increasing linearity in an SAR ADC is by using Data Weighted Averaging (DWA) for the MSB. DWA involves switching between multiple capacitors of the same value. Using multiple capacitors for the same value can be helpful because the average value of the multiple capacitors is more likely to be closer to the desired MSB value than a single capacitor (e.g., due to error in manufacturing). However, DWA is generally only useful for thermometric digital to analog converters (DACs), in which the DAC is not scaled. When the DAC includes scaling, such as binary scaling, the linearity performance of DWA diminishes.

Another method of increasing linearity in an SAR ADC involves using mismatch error shaping (MES). MES operates by sampling from a top plate of capacitors of an ADC in order to add the LSB error from a previous sample to the current input in the analog domain and removing the same error from the digital domain. However, conventional MES is only useful with top plate sampling and is incompatible with bottom plate sampling.

### SUMMARY

This specification describes an ADC that uses bottom-plate sampling to convert a continuous analog waveform into a discrete digital representation. The ADC includes a first DAC array which provides the MSBs of the conversion, and the ADC includes second and third DAC arrays which can each provide the LSBs of the conversion. The ADC can switch between two configurations, wherein in each configuration one of the LSB DAC arrays provides the LSB of the conversion, and the other LSB DAC array provides the error in the previous conversion. Switching between the two configurations allows for the ADC to use bottom-plate sampling, which provides a high linearity, and to involve mismatch error shaping, which increases the accuracy of the conversion when there are mismatched capacitors.

Particular embodiments of the subject matter described in this specification can be implemented so as to realize one or more of the following advantages. For example, certain embodiments increase the linearity of the conversion, e.g., through bottom plate sampling. Additionally, some embodiments reduce errors in the MSB of the conversion, e.g., through data weighted averaging. Another advantageous embodiment allows for bottom plate sampling and mismatch error shaping, which further increases the linearity of the conversion.

In an aspect, an analog-to-digital (ADC) converter includes a most-significant-bit (MSB) digital-to-audio converter (DAC) array configured to generate respective sample values for one or more most-significant bits of an output analog-to-digital value, a first least-significant-bit (LSB) DAC array configured to generate respective sample values for one or more least-significant bits of the output ADC value, a second LSB DAC array configured to generate respective sample values for the one or more least-significant bits of the output ADC value, wherein each DAC array of the first LSB DAC array and the second LSB DAC array is configured to alternate between generating an output ADC bit value and a mismatch error value for the output ADC bit value.

In some implementations, the MSB DAC array is configured to generate the sample values using data weighted averaging.

In some implementations, the first LSB DAC and the second LSB DAC are configured to generate the respective sample values using bottom-plate sampling.

In some implementations, the first LSB DAC and the second LSB DAC are configured to generate respective sample values using mismatch error shaping with bottom-plate sampling.

In some implementations, the MSB DAC array comprises multiple capacitors having substantially the same value, each of the multiple capacitors representing half of a largest value generated by the analog-to-digital converter.

In some implementations, wherein the first LSB DAC array comprises multiple capacitors with substantially different values, each of the multiple capacitors having a smaller value than a most-significant bit of the output ADC value.

In some implementations, each of the multiple capacitors in the first LSB DAC array follow a doubling sequence.

In some implementations, the first LSB DAC array comprises multiple capacitors, and the second LSB DAC array contains multiple capacitors that are substantially the same as the capacitors of the first LSB DAC array.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a diagram of an example system.

FIG. 2A illustrates a simulation of an example system.

FIG. 2B is a plot illustrating a signal to noise distortion ratio of the system of FIG. 2A.

FIG. 3 is a flowchart of an example process for sampling an analog-to-digital converter.

FIG. 4 is a behavioral model of a bottom plate sampled ADC.

Like reference numbers and designations in the various drawings indicate like elements.

### DETAILED DESCRIPTION

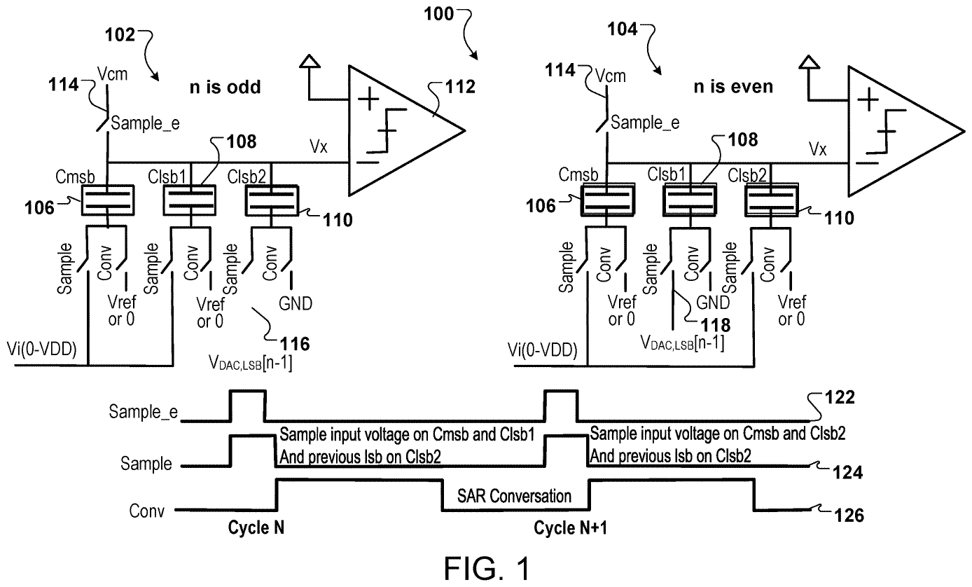

FIG. 1 is a diagram of an example system 100. The system 100 includes an audio-to-digital converter (ADC) 100 in a first configuration 102 and in a second configuration 104. The system 100 can switch between the first configuration 102 and the second configuration 104 to provide a successive approximation (SAR) ADC with high linearity. In the first configuration 102, multiple digital to analog converter (DAC) arrays 106, 108, 110 are electrically connected to a comparator 112. Each DAC array 106, 108, 110 includes capacitors which can provide voltage values to the comparator 112. The first DAC array 106 contains one or multiple capacitors that have a same capacitance value, and therefore each provide substantially the same voltage value to the comparator 112. Providing multiple capacitors with the same value can reduce errors resulting from the capacitance values, e.g., due to manufacturing tolerances. For example, data weighted averaging (DWA) can utilize multiple capacitors with substantially the same capacitance value to reduce errors from slight variations in the capacitance value. Each capacitor in the first DAC array 106 represents the most significant bit (MSB) of the conversion. The MSB is half of the largest value that the ADC can provide.

The second DAC array 108 contains one or multiple capacitors. In implementations with multiple capacitors, each capacitor has a different capacitance value. For example, the capacitors can provide voltages that follow a doubling sequence, e.g., capacitor values are doubled along the array. In some examples, the voltages do not follow a doubling sequence. For example, each capacitor can provide a voltage that is greater than the previous capacitor by a predetermined step value, e.g., one volt, ten volts, or 100 volts.

The capacitors in the second DAC array 108 represent the least significant bits (LSB) of the conversion. For example, the LSB can be any value that is smaller than the MSB. In some implementations, the MSB provides the largest bit in the binary search, and the LSB provides one bit that is smaller than the MSB. In other implementations, the MSB provides the largest bit in the binary search, and the LSB provides ten bits which are each smaller than the MSB. Each additional bit provided by the LSB makes the conversion more precise. For example, the ADC is limited to the precision of the LSB, so providing ten bits in the LSB is more precise than providing one bit. In some implementations, the LSB can provide one to ten additional bits.

The largest capacitor in the second DAC array 108 can provide half the capacitance of a capacitor in the first DAC array 106. For example, if the largest capacitor in the second DAC array provides 16 volts, then each capacitor in the first DAC array can provide 32 volts. The third DAC array 110 array is substantially identical to the second DAC array 108, and contains capacitors with the same capacitance values as the second DAC array 108.

The system 100 in the first configuration 102 can use a binary search process to determine a digital output for an incoming signal sample 114. The comparator 112 compares the incoming signal sample 114 with an approximate value of a first capacitance value provided by one of the capacitors in the first DAC array 106. If the comparator determines that the sample value is greater than the first capacitance provided by the first DAC array 106, then the first capacitance is retained and a second capacitance provided by the largest capacitor in the second DAC array is added to the approximate value. However, if the comparator determines that the sample value is not greater than the first capacitance, then the first capacitance is omitted and the sample is compared with an approximate value of the second capacitance. This process is repeated until all of the capacitors in the second DAC array have been either added to the approximate value or omitted from the approximate value. Each configuration 102, 104 operates by sampling the bottom plate of the capacitors in the DAC arrays. Sampling the bottom plate is advantageous and increases the linearity of the conversion.

Errors in the capacitance values of the capacitors (e.g., due to manufacturing tolerances) can cause ADCs to have corresponding errors in the conversion. This error is also referred to as a mismatch error. The system 100 allows subtraction of the error in the LSB from the next sequential sample in bottom plate sampling by providing two configurations 102, 104 and switching, e.g., with a switch, between the two configurations 102, 104 after every iteration of sampling. For example, configuration 102 provides a second input 116 into the third DAC array 110, which can provide a voltage which corresponds to the error of the LSB in the previous sample. In the next iteration, the system utilizes configuration 104. In configuration 104, a second input 118 is provided into the second DAC array 108. The second input 118 provides a voltage which corresponds to the error of the LSB in the previous sample. In other words, for every iteration in which the second DAC array is used to approximate the value of the sample, e.g., through successive-approximation, the third DAC array receives the previous error in the LSB as input 116. For every iteration in which the third DAC array is used to approximate the value of the sample, the second DAC array receives the previous error in the LSB as input 118. These additional inputs and DAC arrays allow the error in the LSB to be accounted for while also providing bottom plate sampling. Both of these features increase the linearity of the conversion, e.g., increasing the SNDR and the accuracy of the conversion.

Three signals 122, 124, 126 are illustrated at the bottom of FIG. 1. The signals 122, 124, 126 illustrate the timing of switch closures are orchestrated to achieve the described LSB correction and the ping-pong switching between the two LSB-DACs. The signal 122 illustrates the input signal 114. The increase in the signal 122 is the sample voltage to be converted by the ADC. The signal 124 illustrates the sample voltage, e.g., the input signal 122, and the additional error input 116 into the ADC 100. As illustrated, the signal 124 is slightly larger than the input signal 122. The signal 124 is slightly larger because it includes the error in the LSB as an additional input. The signal 126 illustrates the output of the ADC 100 as a result of the signal 124. The ADC 100 converts the signal 124, e.g., the input signal 114 plus the error 116, into a digital signal. The ADC 100 outputs the signal 126 after the signal 124 is provided as input. This is repeated for each cycle of sampling, e.g., cycle N, N+1.

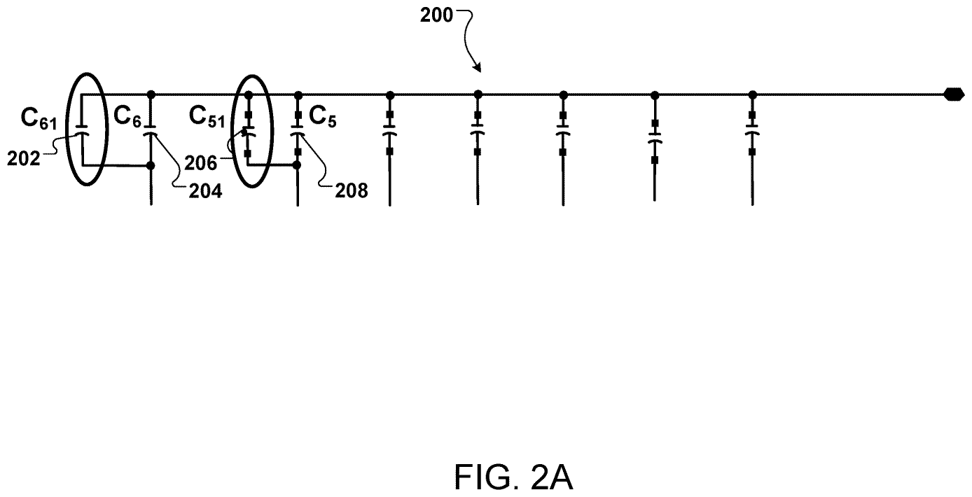

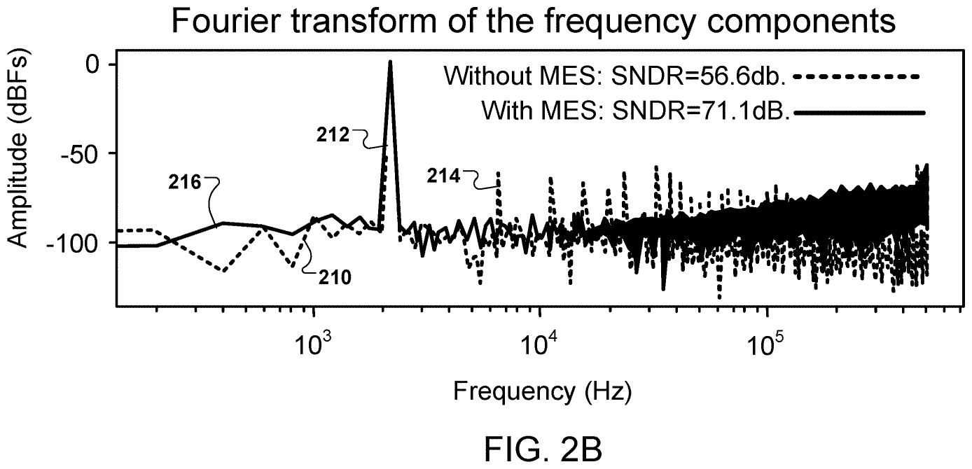

FIG. 2A illustrates the results of a simulation of an analog-to-digital converter 200 using techniques described in this specification. The ADC 200 has capacitors with values that simulate manufacturing variations that would be encountered using actual physical devices. Ideally, capacitors would provide their exact intended capacitance values. However, in real world systems, capacitors can provide slightly different values than the intended capacitance values. The different values in the simulated converter 200 simulate differences in capacitance values, e.g., due to manufacturing tolerances. In the ADC 200, a first capacitor 202 provides a capacitance value which is four fifths of the capacitance value of the corresponding capacitor 204. The first capacitor 202 and the second capacitor 204 can have the same intended value. Similarly, a third capacitor 206 provides a capacitance value which is three fifths of the capacitance value of corresponding capacitor 208, even though the third capacitor 206 and the fourth capacitor 208 may have the same intended value. The simulated converter 200 provides a simulation of a real world converter by providing capacitors with slightly different values.

FIG. 2B illustrates the linearity, in particular the SNDR, of the ADC 200 using different sampling techniques. For example, sample 210 illustrates the SNDR of the ADC 200 without using the technique described above. Sample 210 illustrates the SNDR of the ADC without compensating for the mismatch error between the capacitors 202, 204 and between the capacitors 206, 208. The SNDR is calculated by integrating the noise and distortion from 0 kHz to 20 kHz. As illustrated, the SNDR of the sample 210 is 56.6 decibels (dB). After converting a received signal and providing the desired signal 212, the sample 210 also provides a number of undesired signals 214, which correspond to harmonics, e.g., the 3^{rd} order harmonic, the 5^{th} order harmonic, etc. Each of the undesired signals 214 reduces the linearity and the SNDR of the sample 210.

In comparison, sample 216 illustrates the SNDR of the ADC 200 while using the technique described above (i.e., switching between a first configuration and a second configuration to subtract the error in the LSB). Sample 216 illustrates the SNDR of the ADC while compensating for the error between the capacitors 202, 204 and between the capacitors 206, 208. As illustrated, the SNDR of the sample 214 is 71.1 dB. After providing the desired signal 212, the sample 216 does not provide the undesired signals 214 which are provided by the sample 210. The reduction of undesired signals 214 significantly increases the linearity and the SNDR of the sample 216, which indicates that the sample 216 is a more accurate conversion of the signal.

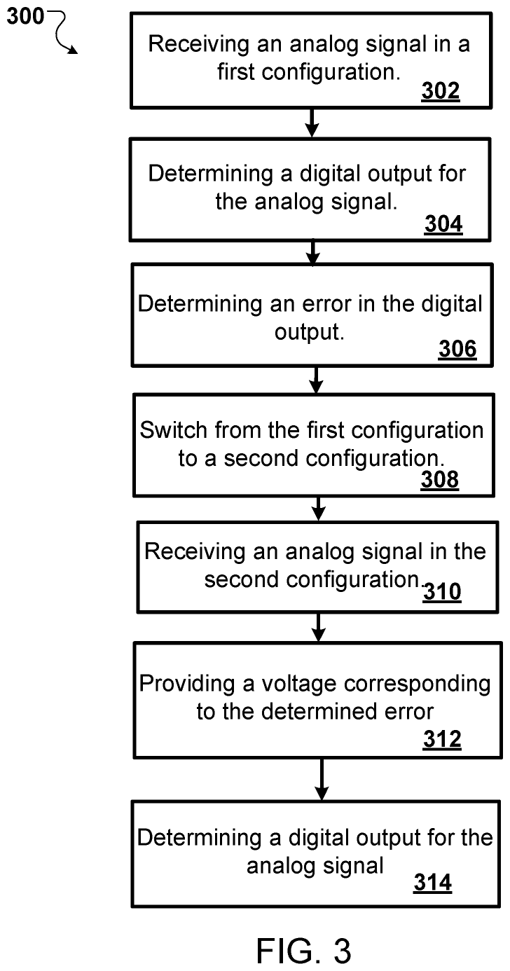

FIG. 3 illustrates a flowchart of an example process 300 for sampling an analog-to-digital converter. The example process can be performed by one or more components of an analog-to-digital converter. The example process will be described as being performed by, e.g., the ADC 100 of FIG. 1, configured accordingly in accordance with this specification.

First, the ADC receives an analog signal in a first configuration (302). For example, the first configuration can be similar to configuration 102 of the system 100 described above. The first configuration can operate by sampling the bottom plate of the capacitors in the DAC arrays. Sampling the bottom plate is advantageous and increases the linearity of the conversion.

The ADC determines a digital output for the received analog signal (304). For example, determining a digital output can include successive approximation. As described above, the ADC can include multiple DAC arrays to determine a digital output through a binary search process.

The ADC determines an error in the digital output (306). For example, determining the error can include determining an error of the LSB in the sample. Determining the error of the LSB can include holding the previous LSB code, i.e., which capacitors were contributing to the approximation, during the sampling.

The ADC switches from the first configuration to a second configuration (308). For example, the second configuration can be similar to configuration 104 described above. The ADC can switch between the first configuration and the second configuration as described above.

The ADC receives an analog signal in the second configuration (310). For example, the second configuration can have an input to receive the analog signal, as described above.

The ADC provides a voltage corresponding to the determined error (312). For example, as described above, configuration 104 provides a second input 118 to provide a voltage which corresponds to the error of the LSB in the previous sample. In some implementations, the input voltage can be the error of the LSB with opposite polarity.

The ADC determines a digital output for the analog signal (314). When the ADC is provided the previous mismatch error in the LSB as an additional input, the determined digital output accounts for the error while also providing bottom plate sampling, as described above.

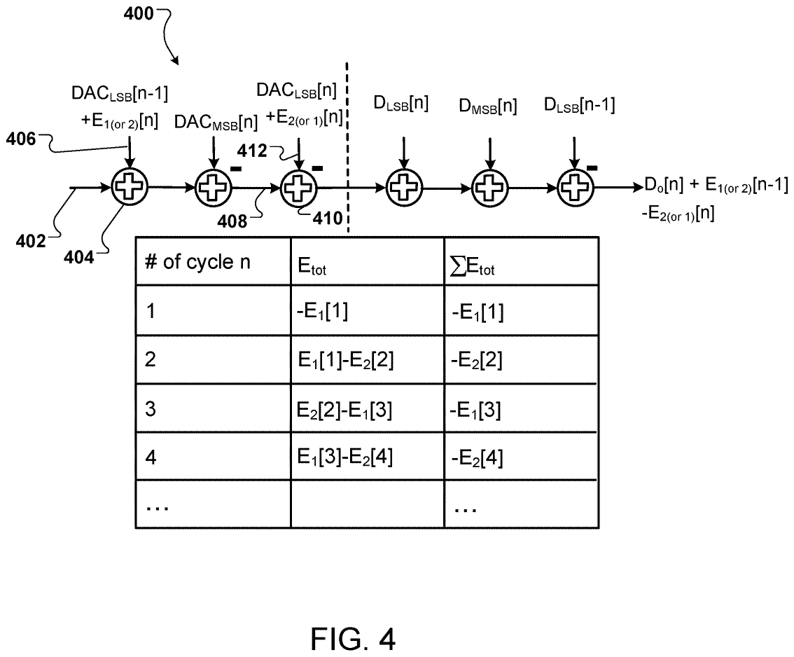

FIG. 4 illustrates a behavioral model 400 of a bottom plate sampled SAR-ADC. For example, the ADC can ping-pong between two LSB DAC's as described above. Both mismatch errors can be first order high pass filtered. As illustrated, when either LSB DAC receives a signal, the previous error is added as an additional input. For example, a signal 402 received at DAC_{LSB}[n−1] 404 has the previous error E₁₍ₒᵣ₂₎[n] 406 added to the signal. The next LSB signal 408 is received at DAC_{LSB}[n] 410, and the previous error E₂₍ₒᵣ₁₎[n] 412 is added as an additional input. As illustrated, the error ping-pongs between E_{1(or 2)} 406 and E_{2(or 1)} 412. This illustrates that the error corresponds to the opposite DAC as the process ping-pongs between the two LSB DAC's.

Embodiments of the subject matter and the functional operations described in this specification can be implemented in digital electronic circuitry in computer hardware, including the structures disclosed in this specification and their structural equivalents, or in combinations of one or more of them. The processes and logic flows can also be performed by special purpose logic circuitry, e.g., an FPGA or an ASIC, or by a combination of special purpose logic circuitry and one or more programmed computers.

In addition to the embodiments described above, the following embodiments are also innovative:

Embodiment 1 is an analog-to-digital converter (ADC) comprising:
a most-significant-bit (MSB) digital-to-audio converter (DAC) array configured to generate respective sample values for one or more most-significant bits of an output analog-to-digital value;
a first least-significant-bit (LSB) DAC array configured to generate respective sample values for one or more least-significant bits of the output ADC value;
a second LSB DAC array configured to generate respective sample values for the one or more least-significant bits of the output ADC value,
wherein each DAC array of the first LSB DAC array and the second LSB DAC array is configured to alternate between generating an output ADC bit value and a mismatch error value for the output ADC bit value.

Embodiment 2 is the ADC of embodiment 1, wherein the MSB DAC array is configured to generate the sample values using data weighted averaging.

Embodiment 3 is the ADC of any one of embodiments 1-2, wherein the first LSB DAC array and the second LSB DAC array are configured to generate the respective sample values using bottom-plate sampling.

Embodiment 4 is the ADC of embodiment 3, wherein the first LSB DAC array and the second LSB DAC array are configured to generate respective sample values using mismatch error shaping with bottom-plate sampling.

Embodiment 5 is the ADC of embodiment 3, wherein the MSB DAC array comprises multiple capacitors having substantially the same value, each of the multiple capacitors representing half of a largest value generated by the analog-to-digital converter.

Embodiment 6 is the ADC of any one of embodiments 1-5, wherein the first LSB DAC array comprises multiple capacitors with substantially different values, each of the multiple capacitors having a smaller value than a most-significant bit of the output ADC value.

Embodiment 7 is the ADC of any one of embodiments 1-6, wherein each of the multiple capacitors in the first LSB DAC array follow a doubling sequence.

Embodiment 8 is the ADC of any one of embodiments 1-7, wherein the first LSB DAC array comprises multiple capacitors, and the second LSB DAC array contains multiple capacitors that are substantially the same as the capacitors of the first LSB DAC array.

Embodiment 9 is a method performed by an analog-to-digital converter (ADC), the method comprising:
generating, by a most-significant-bit (MSB) digital-to-audio converter (DAC) array of the ADC, respective sample values for one or more most-significant bits of an output analog-to-digital value;
generating, by a first least-significant-bit (LSB) DAC array of the ADC, respective sample values for one or more least-significant bits of the output ADC value;
generating, by a second LSB DAC array of the ADC, respective sample values for the one or more least-significant bits of the output ADC value; and
alternating, by each DAC array of the first LSB DAC array and the second LSB DAC array, between generating an output ADC bit value and a mismatch error value for the output ADC bit value.

Embodiment 10 is the method of embodiment 9, further comprising generating, by the MSB DAC array, the sample values using data weighted averaging.

Embodiment 11 is the method of any one of embodiments 9-10, wherein generating, by the first LSB DAC array and the second LSB DAC array, the respective sample values comprises generating the sample values using bottom-plate sampling.

Embodiment 12 is the method of embodiment 11, wherein generating, by the first LSB DAC array and the second LSB DAC array, the respective sample values comprises generating the sample values using mismatch error shaping with bottom-plate sampling.

Embodiment 13 is the method of embodiment 11, wherein the MSB DAC array comprises multiple capacitors having substantially the same value, each of the multiple capacitors representing half of a largest value generated by the analog-to-digital converter.

Embodiment 14 is the method of any one of embodiments 9-13, wherein the first LSB DAC array comprises multiple capacitors with substantially different values, each of the multiple capacitors having a smaller value than a most-significant bit of the output ADC value.

Embodiment 15 is the method of any one of embodiments 9-14, wherein each of the multiple capacitors in the first LSB DAC array follow a doubling sequence.

Embodiment 16 is the method of any one of embodiments 9-15, wherein the first LSB DAC array comprises multiple capacitors, and the second LSB DAC array contains multiple capacitors that are substantially the same as the capacitors of the first LSB DAC array.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain some cases, multitasking and parallel processing may be advantageous.

What is claimed is:

1. An analog-to-digital converter (ADC) comprising:
a most-significant-bit (MSB) digital-to-audio converter (DAC) array configured to generate respective sample values for one or more most-significant bits of an output analog-to-digital value;
a first least-significant-bit (LSB) DAC array configured to generate respective sample values for one or more least-significant bits of the output ADC value;
a second LSB DAC array configured to generate respective sample values for the one or more least-significant bits of the output ADC value,
wherein each DAC array of the first LSB DAC array and the second LSB DAC array is configured to alternate between generating an output ADC bit value and a mismatch error value for the output ADC bit value.

2. The ADC of claim 1, wherein the MSB DAC array is configured to generate the sample values using data weighted averaging.

3. The ADC of claim 1, wherein the first LSB DAC array and the second LSB DAC array are configured to generate the respective sample values using bottom-plate sampling.

4. The ADC of claim 3, wherein the first LSB DAC array and the second LSB DAC array are configured to generate respective sample values using mismatch error shaping with bottom-plate sampling.

5. The ADC of claim 3, wherein the MSB DAC array comprises multiple capacitors having substantially the same value, each of the multiple capacitors representing half of a largest value generated by the analog-to-digital converter.

6. The ADC of claim 1, wherein the first LSB DAC array comprises multiple capacitors with substantially different values, each of the multiple capacitors having a smaller value than a most-significant bit of the output ADC value.

7. The ADC of claim 1, wherein each of the multiple capacitors in the first LSB DAC array follow a doubling sequence.

8. The ADC of claim 1, wherein the first LSB DAC array comprises multiple capacitors, and the second LSB DAC array contains multiple capacitors that are substantially the same as the capacitors of the first LSB DAC array.

9. A method performed by an analog-to-digital converter (ADC), the method comprising:
generating, by a most-significant-bit (MSB) digital-to-audio converter (DAC) array of the ADC, respective sample values for one or more most-significant bits of an output analog-to-digital value;
generating, by a first least-significant-bit (LSB) DAC array of the ADC, respective sample values for one or more least-significant bits of the output ADC value;
generating, by a second LSB DAC array of the ADC, respective sample values for the one or more least-significant bits of the output ADC value; and
alternating, by each DAC array of the first LSB DAC array and the second LSB DAC array, between generating an output ADC bit value and a mismatch error value for the output ADC bit value.

10. The method of claim 9, further comprising generating, by the MSB DAC array, the sample values using data weighted averaging.

11. The method of claim 9, wherein generating, by the first LSB DAC array and the second LSB DAC array, the respective sample values comprises generating the sample values using bottom-plate sampling.

12. The method of claim 11, wherein generating, by the first LSB DAC array and the second LSB DAC array, the respective sample values comprises generating the sample values using mismatch error shaping with bottom-plate sampling.

13. The method of claim 11, wherein the MSB DAC array comprises multiple capacitors having substantially the same value, each of the multiple capacitors representing half of a largest value generated by the analog-to-digital converter.

14. The method of claim 9, wherein the first LSB DAC array comprises multiple capacitors with substantially different values, each of the multiple capacitors having a smaller value than a most-significant bit of the output ADC value.

15. The method of claim 9, wherein each of the multiple capacitors in the first LSB DAC array follow a doubling sequence.

16. The method of claim 9, wherein the first LSB DAC array comprises multiple capacitors, and the second LSB DAC array contains multiple capacitors that are substantially the same as the capacitors of the first LSB DAC array.
